(19) United States
(12) Patent Application Publication
(10) Pub. No.: US 2026/0018854 A1
(43) Pub. Date: Jan. 15, 2026

(54) SEMICONDUCTOR LIGHT-EMITTING DEVICE AND ELECTRONIC DEVICE HAVING THE SAME

(71) Applicant: HON HAI PRECISION INDUSTRY CO., LTD., New Taipei (TW)

(72) Inventor: SHUN-TSENG CHEN, New Taipei (TW)

(21) Appl. No.: 19/260,459

(22) Filed: Jul. 5, 2025

(30) Foreign Application Priority Data
Jul. 15, 2024 (CN) 202410944733.4

(51) Int. Cl. H01S 5/023; G01S 7/481; H01S 5/02253

(52) U.S. Cl. CPC H01S 5/023; H01S 5/02253; G01S 7/4814

(57) ABSTRACT

The present disclosure provides a semiconductor light-emitting device and an electronic device with the semiconductor light-emitting device. The semiconductor light-emitting device includes a substrate, a lens assembly and a light-emitting unit. The substrate includes a metal substrate and an insulating layer covered on an outer surface of the metal substrate. The substrate also includes a first surface 101 and a second surface 102. The first surface includes a chip mounting area and a lens mounting area that are connected to each other. The lens assembly is disposed on the lens mounting area. The light-emitting unit is disposed on the chip mounting area. The lens assembly is located at a light emitting path of the light-emitting unit.

### FIELD

The subject matter relates to semiconductor packaging, and more particularly, to a semiconductor light-emitting device and an electronic device having the semiconductor light-emitting device.

### BACKGROUND

Light Detection and Ranging system (LiDAR) is a radar system that uses laser beams to detect distance, direction, height, speed, and shape of a target. A size of the LiDAR may be large, and dimensional tolerances of the LiDAR may also be large. Also, a manufacturing process of the LiDAR may be complex and costly.

Therefore, there is room for improvement in the art.

### BRIEF DESCRIPTION OF THE DRAWINGS

Implementations of the present technology will now be described, by way of example only, with reference to the attached figures.

FIG. 1 is a diagrammatic view of a semiconductor light-emitting device according to an embodiment of the present disclosure.

FIG. 2 is a diagrammatic view of a semiconductor light-emitting device according to another embodiment of the present disclosure.

FIG. 3 is a diagrammatic view of a semiconductor light-emitting device according to yet another embodiment of the present disclosure.

FIG. 4 is a top view of the semiconductor light-emitting device shown in FIG. 3.

FIG. 5 is a diagrammatic view of a semiconductor light-emitting device according to yet another embodiment of the present disclosure.

FIG. 6 is a diagrammatic view of an electronic device according to an embodiment of the present disclosure.

### DETAILED DESCRIPTION

It will be appreciated that for simplicity and clarity of illustration, where appropriate, reference numerals have been repeated among the different FIG.s to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

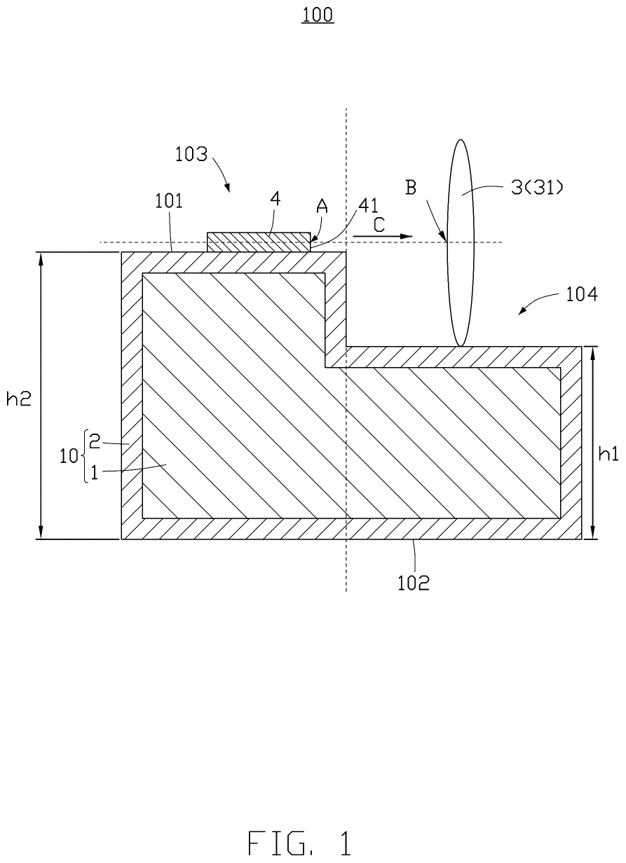

Referring to FIG. 1, a semiconductor light-emitting device 100 is provided according to an embodiment of the present disclosure. The semiconductor light-emitting device 100 includes a substrate 10, a lens assembly 3 and a light-emitting unit 4. The substrate 10 includes a metal substrate 1 and an insulating layer 2 covering at least a portion of an outer surface of the metal substrate 1. The substrate 10 also includes a first surface 101 and a second surface 102 opposite to the first surface 101. Both of the first surface 101 and the second surface 102 are surfaces of the insulating layer 2 away from the metal substrate 1. The first surface 101 includes a chip mounting area 103 and a lens mounting area 104 connected to each other. The lens assembly 3 is disposed on the lens mounting area 104. The light-emitting unit 4 is disposed on the chip mounting area 103. The lens assembly 3 is located at a light emitting path of the light-emitting unit 4.

In at least one embodiment, the lens assembly 3 includes at least one lens 31 for spot shaping, which can correct or shape a light beam C emitted by the light-emitting unit 4. As shown in FIG. 1, the light-emitting unit 4 includes a light-emitting surface 41 facing the lens assembly. The light-emitting surface 41 is configured for emitting the light beams, and the light-emitting surface 41 includes a center B. The lens assembly 3 includes a center B. The center B and the center A are located on a same straight line, so that the light beam C emitted by the light-emitting unit 4 is directly travelled toward the center B of the lens assembly 3. That is, a line defined by the center B and the center A coincides with the light emitting path of the light-emitting unit 4.

In at least one embodiment, the insulating layer 2 covers an entire outer surface of the metal substrate 1, so that the substrate 10 forms an insulating substrate.

In at least one embodiment, a height H1 between the lens mounting area 104 and the second surface 102 is less than a height H2 between the chip mounting area 103 and the second surface 102. A height difference is formed between the chip mounting area 103 and the lens mounting area 104, such that the center A of the light-emitting unit 4 and the center B of the lens assembly 3 may be on a same straight line. The lens assembly 3 is used to correct or shape the light beam C. If an alignment accuracy between the lens assembly 3 and the light-emitting unit 4 is low, an accuracy of the correction or shaping of the light beam C is low, which cannot meet requirements of the semiconductor light-emitting device 100.

In an existing semiconductor light-emitting device, the substrate is ceramic substrate. The processing of the ceramic substrate is more difficult, and the dimensional tolerance is large. Thus, the alignment accuracy between the light-emitting unit and the lens on the ceramic substrate is low. In the present application, the metal substrate 1 and the insulating layer 2 cooperatively form the substrate 10 that is electrically insulated. Compared with the ceramic substrate, the substrate 10 is easier to be processed. During the processing process of the substrate 10, the dimensional accuracy is high and the thickness tolerance is small. The dimensional accuracy and thickness tolerance in the processing process of the substrate 10 can both be less than ±0.01 mm. Also, the accuracy of the height difference formed between the chip mounting area 103 and the lens mounting area 104 is high, thereby improving the assembly accuracy of the light-emitting unit 4 and the lens assembly 3 on the substrate 10. Thus, the center A of the light-emitting unit 4 and the center B of the lens assembly 3 are on the same straight line. Thereby, the accuracy of correction or shaping of the light beam C is improved.

In at least one embodiment, the insulating layer 2 is an insulating electroplated layer. In one embodiment, an insulating material is deposited on the surface of the metal substrate 1 by electroplating to form the insulating layer 2. In one embodiment, the insulating layer 2 is formed on the entire outer surface of the metal substrate 1. During the manufacturing process, the shape and size of the metal substrate 1 can be cut and molded according to requirements. A molding dimensional tolerance of the metal substrate 1 is small, which is less than ±0.01 mm However, a traditional ceramic substrate is difficult to process, and a dimensional tolerance after cutting and molding is large, which is usually greater than ±0.03 mm. Thus, by replacing the ceramic substrate with the substrate 10 in the present application, the alignment accuracy between the lens assembly 3 and the light-emitting unit 4 is reduced.

In at least one embodiment, a thickness of the insulating layer 2 can be set according to actual needs, and the thickness of the insulating layer 2 can be adjusted by controlling process parameters (such as electroplating time) of the electroplating process.

In at least one embodiment, the light-emitting unit 4 is a laser chip, and specifically may be an LED chip.

With the above configuration, the semiconductor light-emitting device 100 has the following beneficial effects:
(1) The metal substrate 1 and the insulating layer 2 cooperatively form the substrate 10 which is easy to be processed. The size of the substrate 10 can be designed according to actual needs, which is flexible to be design. Moreover, since the existing ceramic substrate is not used, there is no need to introduce a semiconductor manufacturing process. A structural design of the substrate 10 is more flexible, which can product various specifications. A production cycle of the semiconductor light-emitting device 100 is short, a cost is low, a process stability is high, and a yield is high. It is suitable for the rapid development of small-batch of the semiconductor light-emitting device 100.
(2) During the processing of the substrate 10, the dimensional accuracy is high and the thickness tolerance is small, which is beneficial to improving the assembly accuracy of the semiconductor light-emitting device 100, so as to improve the alignment accuracy between the light-emitting unit 4 and the lens assembly 3. Therefore, the accuracy of correction or shaping of the light beam C is improved.
(3) The insulating layer 2 is formed on the surface of the metal substrate 1 by insulating electroplating. The thickness of the insulating layer 2 is more uniform, which is beneficial to further reducing the dimensional tolerance of the substrate 10.
(4) The metal substrate 1 and the insulating layer 2 cooperatively form the substrate 10 that is electrically insulated. The heat dissipation effect of the substrate 10 is also improved.

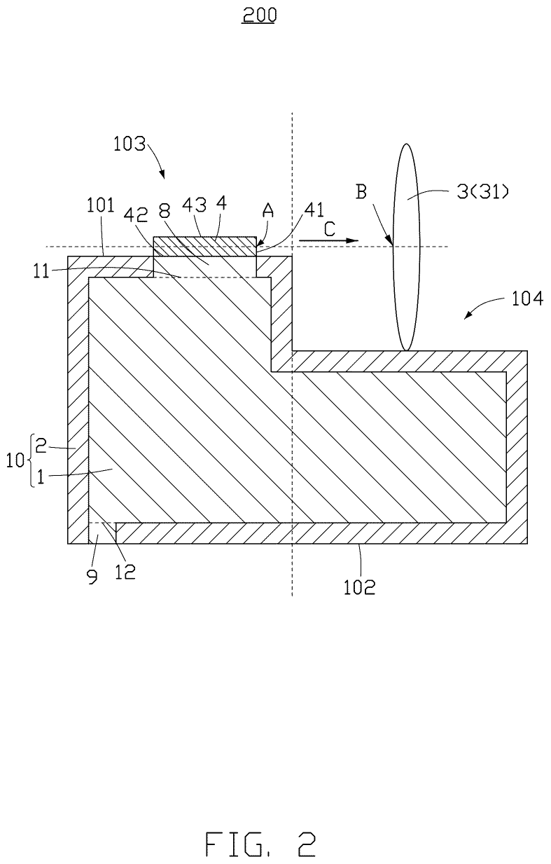

Referring to FIG. 2, a semiconductor light-emitting device 200 is provided according to another embodiment of the present disclosure. Compared to the semiconductor light-emitting device 100, the main difference is that the substrate 10 in the semiconductor light-emitting device 200 is electrically connected to the light-emitting unit 4.

In at least one embodiment, a third surface 11 of the metal substrate 1 is partially exposed from the first surface 101, so that the metal substrate 1 can be electrically connected to the light-emitting unit 4. A fourth surface 12 of the metal substrate 1 is partially exposed from the second surface 102, and the fourth surface 12 is electrically connected to other functional devices or ground. Thus, the light-emitting unit 4 can be electrically connected to other functional devices through the metal substrate 1, or connected to ground through the metal substrate 1.

In at least one embodiment, before electroplating the insulating layer 2 on the metal substrate 1, the first surface 11 of the metal substrate 1 can be partially shielded by a mask (not shown), so that the insulating layer 2 will not be formed on the third surface 11 being shielded. The light-emitting unit 4 is connected to the third surface 11 of the metal substrate 1 by a first conductive structure 8. The fourth surface 12 of the metal substrate 1 is connected to ground by a second conductive structure 9.

In at least one embodiment, the first conductive structure 8 may include a conductive solder paste or conductive adhesive.

In at least one embodiment, the second conductive structure 9 may include a conductive solder paste or conductive adhesive.

In at least one embodiment, the light-emitting unit 4 can also connect to other functional elements, such as electronic components or circuit boards, through the metal substrate 1 of the substrate 10. Specifically, according to the position of the functional elements, a portion of the surface of metal substrate 1 corresponding to each of the functional elements is exposed from the insulating layer 2, so that the light-emitting unit 4 and the functional element can be electrically connected to each other.

Compared to the semiconductor light-emitting device 100, the light-emitting unit 4 in the semiconductor light-emitting device 200 can achieve grounding conduction or circuit conduction through the substrate 10. The conduction method is simple, which simplifies the structure of the semiconductor light-emitting device 200 and is conducive to realizing the miniaturization of the semiconductor light-emitting device 200.

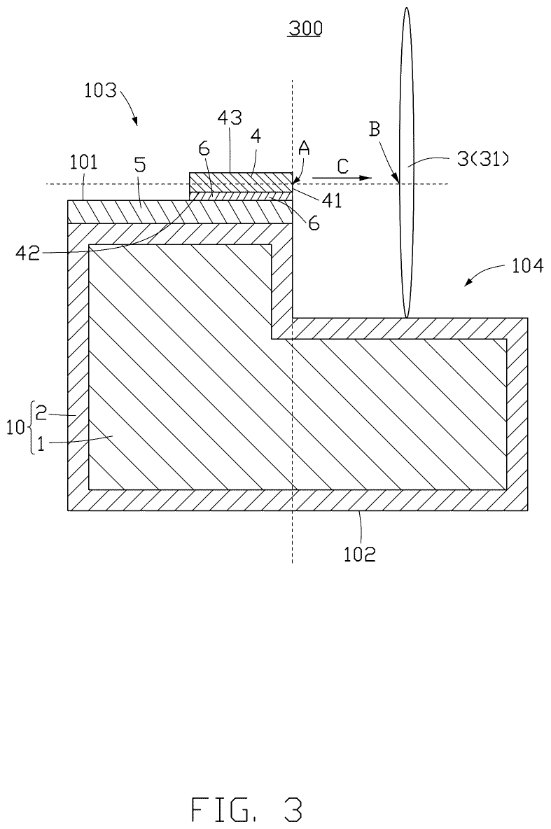

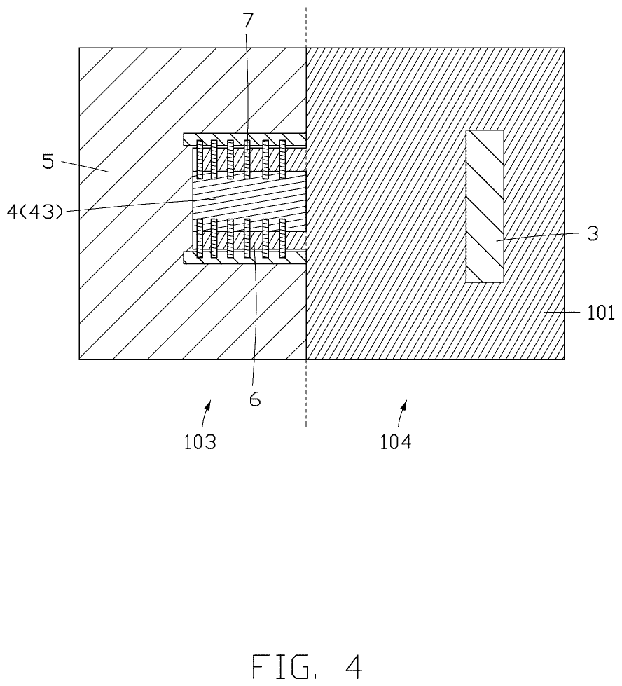

Referring to FIGS. 3 and 4, a semiconductor light-emitting device 300 is provided according to yet another embodiment of the present disclosure. Compared to the semiconductor light-emitting device 100, the main difference is that a circuit board 5 is disposed on the chip mounting area 103, and the light-emitting unit 4 is electrically connected to the circuit board 5.

In at least one embodiment, the light-emitting unit 4 further comprises a back surface 42 and a front surface 43 opposite to the back surface 42. The back surface 42 is connected to the circuit board 5 through an insulating heat-conducting layer 6, and the front surface 43 is electrically connected to the circuit board 5 through a metal wire 7. By adding the insulating heat-conducting layer 6, the stability of the light-emitting unit 4 can be improved, and the heat dissipation of the light-emitting unit 4 can be further improved to reduce overheating damages to the light-emitting unit 4. In one embodiment, the insulating heat-conducting layer 6 includes an insulating heat-conducting adhesive.

Compared to the semiconductor light-emitting device 100, in the semiconductor light-emitting device 300, short-circuit is avoided at the circuit board 5 since the metal substrate 1 is covered with the insulating layer 2. In addition, the light-emitting unit 4, circuits, and other components can be located on the circuit board 5, which improves a packaging density of the semiconductor light-emitting device 300.

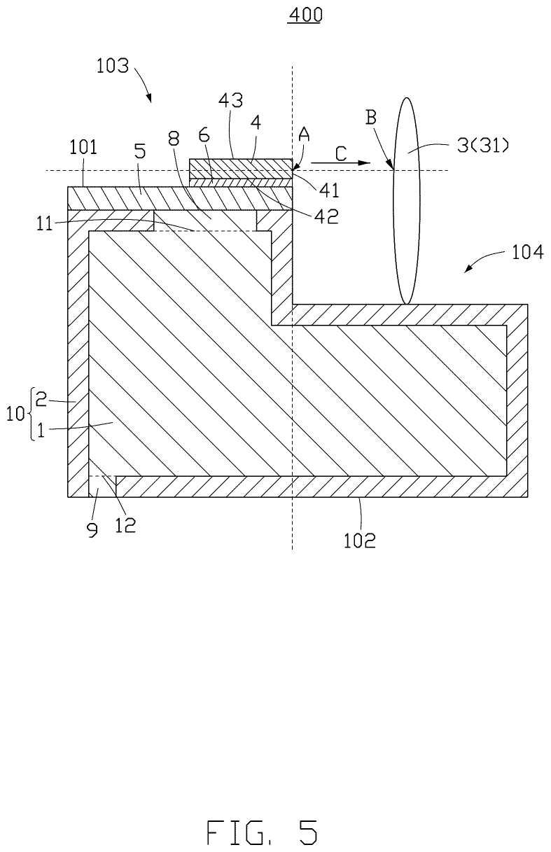

Referring to FIG. 5, a semiconductor light-emitting device 400 is provided according to yet another embodiment of the present disclosure. Compared to the semiconductor light-emitting device 200, the main difference is that a circuit board 5 is disposed on the chip mounting area 103, and the light-emitting unit 4 is electrically connected to the circuit board 5. The circuit board 5 is electrically connected to the metal substrate 1.

In at least one embodiment, the third surface 11 of the metal substrate 1 is partially exposed from the first surface 101, so that the metal substrate 1 can be electrically connected to the circuit board 5. The fourth surface 12 of the metal substrate 1 is partially exposed from the second surface 102, so that the circuit board 5 can be connected to ground through the metal substrate 1.

In at least one embodiment, the circuit board 5 is connected to the third surface 11 of the metal substrate 1 by a first conductive structure 8. The fourth surface 12 of the metal substrate 1 is connected to ground by a second conductive structure 9.

In at least one embodiment, the first conductive structure 8 may include a conductive solder paste or conductive adhesive.

In at least one embodiment, the second conductive structure 9 may include a conductive solder paste or conductive adhesive.

In at least one embodiment, the circuit board 5 can also electrically connect to other functional elements, such as electronic components or other circuit boards, through the metal substrate 1 of the substrate 10.

Compared to the semiconductor light-emitting device 200, in the semiconductor light-emitting device 400, the circuit board 5 is electrically connected to the substrate 10. The circuit board 5 can realize grounding conduction or conduction with other functional elements through the substrate 10. The conduction method is simple, which simplifies the structure of the semiconductor light-emitting device 400 and is conducive to the miniaturization of the semiconductor light-emitting device 400.

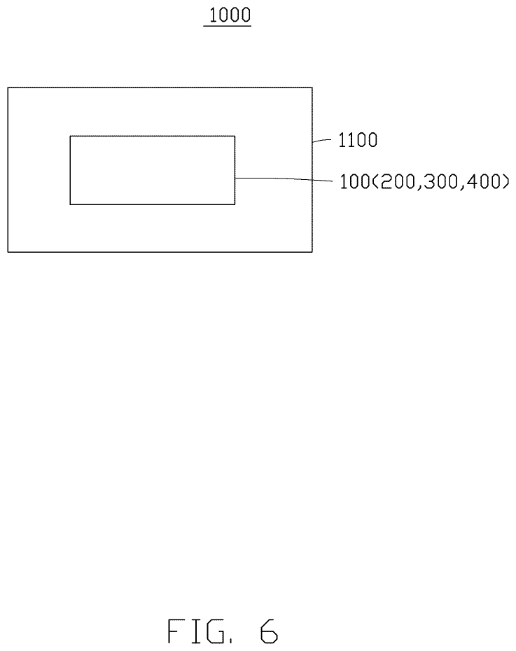

Referring to FIG. 6, an electronic device 1000 is also provided according to an embodiment of the present disclosure. The electronic device 1000 includes a casing 1100 and the semiconductor light-emitting device 100 (200, 300 or 400) mounted on the casing 1100.

The electronic device 1000 is a laser device, which may be applied in a laser detection and ranging system (LiDAR). The semiconductor light-emitting device 100 (200, 300 or 400) can improve the optical accuracy of the electronic device 1000, conducive to the miniaturization of the electronic device 1000, improve the flexibility of the structural design of the electronic device 1000, and reduce the cost of the electronic device 1000.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A semiconductor light-emitting device comprising:
a substrate comprising a metal substrate and an insulating layer covering an outer surface of the metal substrate, the substrate further comprising a first surface and a second surface opposite to the first surface, the first surface and the second surface being surfaces of the insulating layer away from the metal substrate, the first surface comprising a chip mounting area and a lens mounting area connected to each other;
a lens assembly disposed on the lens mounting area; and
a light-emitting unit disposed on the chip mounting area, wherein the lens assembly is located at a light emitting path of the light-emitting unit.

2. The semiconductor light-emitting device according to claim 1, wherein the light-emitting unit comprises an light-emitting surface facing the lens assembly, a line defined by a center of the light-emitting surface and a center of the lens assembly coincides with the light emitting path of the light-emitting unit.

3. The semiconductor light-emitting device according to claim 1, wherein a height between the lens mounting area and the second surface is less than a height between the chip mounting area and the second surface.

4. The semiconductor light-emitting device according to claim 1, wherein the insulating layer covers an entire outer surface of the metal substrate.

5. The semiconductor light-emitting device according to claim 1, wherein the metal substrate is partially exposed from the first surface to form a third surface, the metal substrate is partially exposed from the second surface to form a fourth surface, the third surface is electrically connected to the light-emitting unit, and the fourth surface is configured to be electrically connected to a device or ground.

6. The semiconductor light-emitting device according to claim 5, wherein the light-emitting unit is electrically connected to the third surface through a first conductive structure, and the fourth surface is configured to be electrically connected to the device or ground through a second conductive structure.

7. The semiconductor light-emitting device according to claim 5, further comprising a circuit board disposed on the chip mounting area, wherein the light-emitting unit is electrically connected to the circuit board, and the circuit board is electrically connected to the third surface of the metal substrate.

8. The semiconductor light-emitting device according to claim 1, further comprising a circuit board disposed on the chip mounting area, wherein the light-emitting unit is electrically connected to the circuit board.

9. The semiconductor light-emitting device according to claim 8, wherein the light-emitting unit further comprises a back surface and a front surface opposite to the back surface, the back surface is connected to the circuit board through an insulating heat-conducting layer, and the front surface is electrically connected to the circuit board through a metal wire.

10. The semiconductor light-emitting device according to claim 1, wherein the insulating layer is an insulating electroplated layer.

11. An electronic device comprising:
a casing; and
a semiconductor light-emitting device comprising:
a substrate comprising a metal substrate and an insulating layer covering an outer surface of the metal substrate, the substrate further comprising a first surface and a second surface opposite to the first surface, the first surface and the second surface being surfaces of the insulating layer away from the metal substrate, the first surface comprising a chip mounting area and a lens mounting area connected to each other;
a lens assembly disposed on the lens mounting area; and
a light-emitting unit disposed on the chip mounting area, wherein the lens assembly is located at a light emitting path of the light-emitting unit.

12. The electronic device according to claim 11, wherein the light-emitting unit comprises a light-emitting surface facing the lens assembly, a line defined by a center of the light-emitting surface and a center of the lens assembly coincides with the light emitting path of the light-emitting unit.

13. The electronic device according to claim 11, wherein a height between the lens mounting area and the second surface is less than a height between the chip mounting area and the second surface.

14. The electronic device according to claim 11, wherein the insulating layer covers an entire outer surface of the metal substrate.

15. The electronic device according to claim 11, wherein the metal substrate is partially exposed from the first surface to form a third surface, the metal substrate is partially exposed from the second surface to form a fourth surface, the third surface is electrically connected to the light-emitting unit, and the fourth surface is configured to be electrically connected to a device or ground.

16. The electronic device according to claim 15, wherein the light-emitting unit is electrically connected to the third surface through a first conductive structure, and the fourth surface is configured to be electrically connected to the device or ground through a second conductive structure.

17. The electronic device according to claim 15, further comprising a circuit board disposed on the chip mounting area, wherein the light-emitting unit is electrically connected to the circuit board, and the circuit board is electrically connected to the third surface of the metal substrate.

18. The electronic device according to claim 11, further comprising a circuit board disposed on the chip mounting area, wherein the light-emitting unit is electrically connected to the circuit board.

19. The electronic device according to claim 18, wherein the light-emitting unit further comprises a back surface and a front surface opposite to the back surface, the back surface is connected to the circuit board through an insulating heat-conducting layer, and the front surface is electrically connected to the circuit board through a metal wire.

20. The electronic device according to claim 11, wherein the insulating layer is an insulating electroplated layer.
